(19) United States
(12) Patent Application Publication
(10) Pub. No.: US 2026/0123093 A1
(43) Pub. Date: Apr. 30, 2026

(54) Cell Grid Line Preparation Method and Apparatus

(71) Applicants: BEIJING ZENITHNANO TECHNOLOGY CO., LTD., Beijing (CN); GUANGDONG ZENITHNANO NEW MATERIAL CO., LTD., Guangzhou (CN)

(72) Inventors: Kaiqi PAN, Beijing (CN); Zhicong LI, Beijing (CN); Shudong ZHONG, Beijing (CN); Guanghang YANG, Beijing (CN); Jingjing SHU, Beijing (CN)

(73) Assignees: BEIJING ZENITHNANO TECHNOLOGY CO., LTD., Beijing (CN); GUANGDONG ZENITHNANO NEW MATERIAL CO., LTD., Guangzhou (CN)

(21) Appl. No.: 19/204,677

(22) Filed: May 12, 2025

Related U.S. Application Data
(63) Continuation-in-part of application No. PCT/CN2024/131208, filed on Nov. 11, 2024.

(30) Foreign Application Priority Data
Oct. 31, 2024 (CN) 202411541964.7

(51) Int. Cl. H10F 77/20; H10F 71/00

(52) U.S. Cl. CPC H10F 77/215; H10F 71/00

(57) ABSTRACT

The provided is a cell grid line preparation method and apparatus. The method includes: preparing conductive paste transfer layers corresponding to a front surface and a rear surface of a cell, respectively, on transfer substrates, where the transfer layers each include a grid line pattern trench; uniformly filling conductive paste into the trench; precisely aligning and bonding the front and rear conductive paste transfer layers onto the corresponding cell surfaces, respectively; and performing synchronous transfer of grid line patterns on the front and rear surfaces of the cell by simultaneously applying pressure and temperature to upper and lower parts. The provided adopts simultaneous upper-lower transfer, balancing force distribution to prevent cell microcracks, and significantly enhancing the bonding level between the grid line and the cell surface, as well as the current collection efficiency. The cell grid line preparation apparatus can complete the entire preparation process in a single integrated machine.

### CROSS-REFERENCE TO THE RELATED APPLICATIONS

This application is a continuation-in-part application of International Application No. PCT/CN2024/131208, filed on Nov. 11, 2024, which is based upon and claims priority to Chinese Patent Application No. 202411541964.7, filed on Oct. 31, 2024, the entire contents of which are incorporated herein by reference.

### TECHNICAL FIELD

The present disclosure relates to the technical field of solar cells, and in particular to a cell grid line preparation method and apparatus.

### BACKGROUND

With a global rise in environmental protection awareness and the active advancement of national carbon peaking and carbon neutrality goals, the construction of a novel power system dominated by renewable energy has become a critical development direction in the energy sector. As a core component of the renewable energy sector, the photovoltaic (PV) industry has significantly elevated its status and is embracing unprecedented development opportunities. Solar cells, being the key components of PV systems, directly determine the efficiency and stability of the entire PV systems through their performance optimization and enhancement. Currently, industrialized production of monocrystalline silicon PV cells dominates the solar cell market, accounting for over 90% of total output.

As a vital part of solar cells, electrode grid lines play a decisive role in cell performance. Their primary function is to collect current generated through the PV effect and conduct it to external circuits. Consequently, optimizing the material selection and preparation processes for electrode grid lines has become a crucial pathway to improve the photoelectric conversion efficiency of solar cells. The metal conductive paste, owing to its excellent conductive performance and chemical stability, is now one of the most widely used materials for electrode grid lines.

However, the preparation process of forming PV cell grid lines using conductive paste still faces numerous technical challenges. Traditional screen printing technology benefits from mature processes and widespread equipment availability, but its precision is constrained by screen mesh aperture and printing pressure, making it hard to achieve ultra-fine patterns and high-resolution printing. Additionally, the screen printing process will generate significant waste, leading to substantial material losses. Furthermore, screens have limited lifespans and are costly, resulting in high overall expenses. More critically, the relatively slow speed of screen printing technology cannot meet large-scale production demands, thereby impacting production efficiency.

Specifically, the grid line preparation process via screen printing includes front busbar/finger printing, rear busbar/finger printing, drying, and sintering. While these steps enable the preparation of front and rear busbars/fingers, the entire process remains cumbersome and inefficient. Each printing step requires re-positioning and re-adjusting the screen, increasing operational complexity and prolonging production cycles. Therefore, to overcome the limitations of existing screen printing technology, developing a novel PV cell electrode grid line preparation technology characterized by a simple process, low cost, high production efficiency, and high resolution becomes critically important.

### SUMMARY

An objective of the present disclosure is to provide a cell grid line preparation method, which enables the preparation of micron-scale electrode patterns, simplifies the preparation process, and significantly reduces material consumption to lower production costs. The objective of the present disclosure is achieved through the following technical solution. The cell grid line preparation method includes:
preparing conductive paste transfer layers corresponding to a front grid line and a rear grid line on transfer substrates, respectively, where the conductive paste transfer layers each include grid line pattern trenches;
filling conductive paste into the grid line pattern trench;
aligning and bonding the conductive paste transfer layer corresponding to the front grid line onto a front surface of a cell, and aligning and bonding the conductive paste transfer layer corresponding to the rear grid line onto a rear surface of the cell;
simultaneously applying pressure to the front surface and the rear surface of the cell, and transferring the conductive paste in the grid line pattern trenches onto the front surface and the rear surface of the cell;
converting the transferred conductive paste into the front and rear grid lines.

In an embodiment, the preparing the conductive paste transfer layers includes: coating a water-soluble polymer material on the transfer substrate, drying, and controlling a thickness to fall within 10-50 μm.

In an embodiment, the transfer substrate is a flexible material.

In an embodiment, the grid line pattern trenches are formed in the conductive paste transfer layer by imprinting with a mold.

In an embodiment, a grid line pattern includes a first grid line pattern with a trench depth of 10-50 μm and a trench width of 20-200 μm and a second grid line pattern with a trench depth 6-25 μm and a trench width 3-50 μm.

In an embodiment, the filling conductive paste into the grid line pattern trench includes: filling the conductive paste into the imprinted grid line pattern trench, and scraping off excess conductive paste.

In an embodiment, the transferring is performed at 80-180° C. and 1-20 MPa for 0.5-10 min.

In an embodiment, the transferring the conductive paste in the grid line pattern trenches onto the front surface and the rear surface of the cell includes: first removing the transfer substrate, and then removing the conductive paste transfer layer through a liquid dissolution method.

Additionally, the present disclosure further provides a cell grid line preparation apparatus, capable of implementing the aforementioned cell grid line preparation method in a single integrated machine, thereby enhancing cell production line integration, where the apparatus specifically includes:
transfer substrates;
coating units, each configured to coat the conductive paste transfer layer onto the transfer substrate;
hot-embossing units, each configured to form the grid line pattern trenches in the conductive paste transfer layer;
paste filling units, each configured to fill the conductive paste into the grid line pattern trench;
scraping units, each configured to scrape off excess conductive paste;
transfer units, each configured to align and bond the conductive paste transfer layer onto a cell surface and transfer the conductive paste in the grid line pattern trench onto the cell surface; and
a transport mechanism, configured to transport the cell to a station of the transfer unit; and
where, the apparatus includes the transfer substrates, the coating units, the hot-embossing units, the paste filling units, the scraping units, and the transfer units corresponding to the front grid line and the rear grid line, respectively, enabling simultaneous conductive paste transfer on the front surface and the rear surface of the cell.

In an embodiment, the transfer substrate is configured as a cylindrical roller; and the coating unit, the hot-embossing unit, the paste filling unit, and the scraping unit are sequentially arranged on the cylindrical roller along a rotation direction of the cylindrical roller.

In an embodiment, the transfer substrate is provided with a polygonal cross-section including multiple flat surfaces; and the coating unit, the hot-embossing unit, the paste filling unit, and the scraping unit are sequentially arranged on corresponding surfaces of the transfer substrate along a rotation direction of the transfer substrate.

In an embodiment, the apparatus further includes a moving unit; and the moving unit is configured to synchronously adjust heights of upper and lower transfer substrates of the cell.

In an embodiment, the apparatus further includes a cleaning unit located before a coating station to clean a surface of the transfer substrate.

In an embodiment, the apparatus further includes a drying unit, a cleaning unit, and a sintering unit; the drying unit is configured to dry the conductive paste; the cleaning unit is configured to dissolve and remove the conductive paste transfer layer through a solution method; and the sintering unit is configured to sinter the conductive paste.

Additionally, the present disclosure further provides a cell, including front and rear grid lines, where the front and rear grid lines of the cell are prepared by the aforementioned cell grid line preparation method.

Compared with the prior art, the present disclosure has the following beneficial effects.

The present disclosure forms the grid line pattern trenches in the conductive paste transfer layer through mold imprinting and precisely controls the trench depth and width (e.g., a depth of 10-50 μm and 6-25 μm, and a width of 20-200 μm and 3-50 μm). The present disclosure easily achieves the preparation of micron-scale electrode patterns, enhancing the fineness and resolution of the electrode grid lines, and establishing a solid foundation for further improving the efficiency of solar cells. The method of the present disclosure directly prepares the conductive paste transfer layer on the transfer substrate and completes simultaneous transfer of the front and rear grid lines in a single step, simplifying preparation processes while eliminating the need for multiple printing and positioning operations. Meanwhile, the present disclosure achieves precise filling and scraping of the conductive paste during transfer, effectively reducing material waste.

The present disclosure enables simultaneous transfer on the upper and lower parts of the cell, accomplishing single-step preparation of the front grid lines (including busbars and fingers) and rear grid lines (including busbars and fingers), thereby significantly enhancing production efficiency while reducing preparation steps and time costs. The preparation method of the present disclosure employs a simplified preparation process to achieve simultaneous transfer on the upper and lower parts of the cell, reducing time investment, lowering production costs, and improving production efficiency. Specifically, PVA can be used as a carrier to facilitate tight bonding between the silver paste and the cell, and it is dissolved after transfer to achieve transfer of the conductive paste onto the cell. Through the hot-embossing and transfer technology, the PVA trenches coated with the conductive paste are tightly bonded to the cell, forming the electrode grid lines with specific patterns after heat curing. Finally, the PVA is removed using a solvent. The present disclosure achieves high efficiency and stability in one-step preparation of multiple grid lines.

The cell grid line preparation apparatus of the present disclosure achieves the cell grid line preparation method in a single integrated machine. This is enabled by a highly integrated apparatus design incorporating the transfer substrates, coating units, hot-embossing units, paste filling units, scraping units, transfer units, and transport mechanism. The present disclosure simplifies current grid line electrode production lines, reduces equipment complexity, and achieves full automation from conductive paste coating to grid line transfer, enhancing production line integration and automation levels. The present disclosure is suitable for industrial production, facilitating large-scale production and application.

### BRIEF DESCRIPTION OF THE DRAWINGS

FIG. 1 is a structural schematic flowchart of a cell grid line preparation method according to an embodiment of the present disclosure;

FIG. 2 is a structural schematic diagram of a cell grid line distribution according to an embodiment of the present disclosure;

FIG. 3 is a cross-sectional schematic diagram of a cell grid line according to an embodiment of the present disclosure;

FIG. 4 is a structural schematic diagram of a cell grid line preparation apparatus according to an embodiment of the present disclosure; and

FIG. 5 is a structural schematic diagram of a cell grid line preparation apparatus according to another embodiment of the present disclosure.

Reference Numerals: 100. transfer substrate; 200. conductive paste transfer layer; 210. coating unit; 300. grid line pattern trench; 310. hot-embossing unit; 400. conductive paste; 410. paste filling unit; 420. scraping unit; 500. grid line; 600. transfer unit; 610. drying unit; 620. cleaning unit; and 630. sintering unit.

### DETAILED DESCRIPTION OF THE EMBODIMENTS

To make the above objectives, features and advantages of the present disclosure clearer, the specific implementations of the present disclosure are described in detail below with reference to drawings. It is understandable that the specific embodiments described herein are merely intended to explain the present disclosure, rather than to limit the present disclosure. It should also be noted that for convenience of description, only a partial structure rather than all the structure related to the present disclosure is shown in the drawings. Based on the embodiments of the present disclosure, all other embodiments obtained by those of ordinary skill in the art without creative efforts should fall within the protection scope of the present disclosure.

Moreover, in the present disclosure, the terms “include”, “have”, and any variations thereof are intended to cover non-exclusive inclusion. For example, a process, method, system, product or device that includes a series of steps or units is not limited to the listed steps or units. On the contrary, optionally, it also includes steps or units that are not listed, or optionally also includes other steps or units inherent to the process, method, product or device.

The term “embodiment” mentioned herein means that a specific feature, structure, or characteristic described in combination with the embodiment may be included in at least one embodiment of the present disclosure. The phrase appearing in different parts of the specification does not necessarily refer to the same embodiment or an independent or alternative embodiment exclusive of other embodiments. It may be explicitly or implicitly appreciated by those skilled in the art that the embodiments described in this specification may be combined with another embodiment.

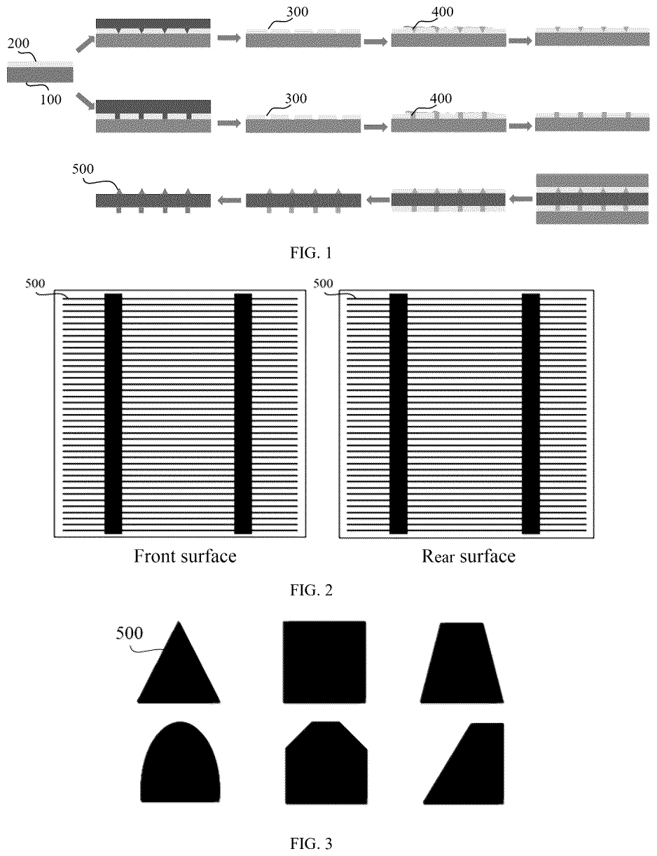

The traditional preparation of grid lines on cells predominantly employs screen printing technology. While this method is mature and widely adopted, it faces challenges such as limitations in precision, material waste, and low production efficiency, which hinder its ability to meet the current PV industry's demands for high efficiency, cost reduction, and large-scale manufacturing. Consequently, there is a pressing need to explore an innovative cell grid line preparation method and apparatus capable of achieving precise preparation of micron-scale electrode patterns, simplifying processes, reducing material consumption, and enhancing production efficiency. To address this, the present disclosure proposes a novel cell grid line preparation method and apparatus that integrates mold imprinting and transfer technologies to improve preparation efficiency and reduce costs while maintaining high precision and high quality. Please refer to FIG. 1, FIG. 1 is a structural flowchart of the cell grid line preparation method. According to a preferred embodiment of the present disclosure, the cell grid line preparation method can significantly minimize material consumption (thereby lowering production costs) and enables stable formation of fine-scale grid lines. The method specifically includes the following steps. Conductive paste transfer layers 200 are prepared on transfer substrates 100, corresponding to front and rear grid lines, respectively. The conductive paste transfer layer 200 includes grid line pattern trenches 300. The grid line pattern trenches 300 are filled with conductive paste 400. The conductive paste transfer layer 200 corresponding to the front grid lines is aligned and bonded to a front surface of a cell, while the conductive paste transfer layer 200 corresponding to the rear grid lines is aligned and bonded to a rear surface of the cell. Pressure is simultaneously applied to the front surface and the rear surface of the cell, such that the conductive paste 400 is transferred from the grid line pattern trenches 300 onto the front surface and the rear surface of the cell. The transferred conductive paste 400 is converted into the front and rear grid lines.

In the present disclosure, the process begins by preparing the conductive paste transfer layers 200 on the transfer substrates 100, corresponding to the front and rear grid lines of the cell, respectively. In this step, two transfer substrates 100 are utilized to prepare the transfer layers. The transfer layers incorporate precisely designed grid line pattern trenches 300, which serve as carriers for the conductive paste 400. The shape, dimensions, and distribution of these trenches are meticulously calculated to ensure optimal conductive performance and photoelectric conversion efficiency of final grid lines 500. Next, a filling technique is employed to uniformly and thoroughly fill the conductive paste 400 into the grid line pattern trenches 300. The specific filling method may be selected as needed. This step should ensure complete coverage of the bottoms and sidewalls of the trenches by the conductive paste 400, while avoiding unnecessary accumulation of paste outside the trenches. This approach minimizes material waste while guaranteeing the quality of the grid lines 500. Specifically, a coating-and-scraping method below can be adopted. Subsequently, the prepared conductive paste transfer layer 200 for the front grid line is precisely aligned and bonded to the front surface of the cell, while the conductive paste transfer layer 200 for the rear grid line is aligned and bonded to the rear surface of the cell. During this step, by controlling the positioning accuracy and bonding level, the contact resistance between the grid lines 500 and the cell surface is minimized, thereby enhancing current collection efficiency.

After aligning and bonding, appropriate pressure and temperature are simultaneously applied to precisely and uniformly transfer the conductive paste 400 from the grid line pattern trenches 300 onto the front and rear surfaces of the cell, leveraging the properties of the transfer substrate 100 and the conductive paste 400. This step enables high-precision replication of the grid line patterns. Moreover, by optimizing pressure and temperature conditions, the flow and curing processes of the conductive paste 400 can be further controlled to achieve a more uniform and dense grid line 500 structure. The transferred conductive paste 400 is then converted into front and rear grid lines with excellent conductive performance and stability through methods such as thermal treatment. Specifically, a conventional sintering process may be employed. This design enhances the mechanical strength and durability of the grid lines 500. Additionally, by optimizing treatment conditions, the microstructure and electrical properties of the grid lines 500 can be adjusted to meet the requirements of diverse application scenarios.

It should be particularly emphasized that the present disclosure adopts a technical solution of simultaneous upper-lower transfer, which enables synchronous transfer of grid line patterns onto both the front and rear surfaces of the cell. This approach demonstrates technical advantages in balancing force distribution, reducing production steps, and improving overall manufacturing efficiency. A precision-engineered imprinting device and process parameters ensure that uniform and consistent pressure is applied to both the front and rear surfaces of the cell during imprinting. This balanced force distribution avoids microcracks in the cell caused by non-uniform pressure, ensures tight bonding between the grid lines 500 and the cell surfaces, and thereby reduces the contact resistance while enhancing current collection efficiency. Furthermore, balanced force distribution minimizes stress concentration during imprinting. In contrast, traditional cell grid line preparation processes often require separate steps to prepare the grid lines 500 on the front and rear surfaces, increasing production complexity and potentially introducing inconsistencies between front and rear grid lines. The simultaneous upper-lower imprinting process consolidates multiple steps (e.g., alignment) into a single operation, streamlining the workflow and improving production efficiency and consistency. By balancing force distribution, reducing production steps, and enhancing overall efficiency, the novel simultaneous upper-lower imprinting process demonstrates significant technical advantages in cell grid line preparation.

Specifically, the preparation of the conductive paste transfer layer 200 proceeds as follows. A water-soluble polymer material is coated onto the transfer substrate 100, dried, and controlled to a thickness of 10-50 μm. The water-soluble polymer material includes, but is not limited to, polyvinyl alcohol (PVA), polyvinyl pyrrolidone (PVP), and polyethylene glycol (PEG). In the present disclosure, the transfer is performed simultaneously on the upper and lower parts of the cell. In a specific implementation, PVA may serve as the primary material for the conductive paste transfer layer. Due to PVA's solubility, the silver paste can be successfully transferred onto the cell. Meanwhile, the hot-embossing and transfer technology ensures tight bonding between the silver paste and the cell, forming stable electrode grid lines. PVA exhibits a glass transition temperature of 75-85° C. and gradually discolors and embrittles when heated above 100° C. in air. Its inherent properties prevent rebound after hot-embossing, thereby maintaining structural integrity. PVA is insoluble in organic solvents such as gasoline, kerosene, vegetable oil, benzene, toluene, dichloroethane, carbon tetrachloride, acetone, ethyl acetate, methanol, and ethylene glycol. Furthermore, PVA is incompatible and non-reactive with the binder in the silver paste and other conductive pastes. It is important to emphasize that PVA represents one specific material choice and an optimal technical solution. Other materials with similar properties may also be used for the conductive paste transfer layer 200, provided they adhere to the following major selection criteria. The material is a water-soluble polymer material, which is incompatible and non-reactive with substances in the paste, and the material is selected according to different paste composition. By following these criteria, the transfer layer can be removed through an aqueous solution without affecting the morphology and distribution of the conductive paste. By combining this approach into the method process of the present disclosure, the removal of the transfer layer is simplified, enhancing the integration of the entire process with production equipment.

The method of the present disclosure leverages precise parameters of hot-embossing unit 310 (e.g., heating temperature, pressure, duration) and high-precision molds to control the size and shape of the PVA-transferred composite conductive grid lines, thereby reducing ohmic losses in the electrode grid lines. PVA is an environmentally friendly, biodegradable material with minimal ecological impact. The room-temperature water-soluble PVA coating significantly reduces demolding costs. The materials and equipment involved are cost-effective and eco-friendly, offering a groundbreaking technology capable of reshaping the current landscape of silver electrode grid line printing in PV cells.

The conductive paste 400 primarily consists of silver paste, which is the conventional choice due to silver's exceptional conductive performance and chemical stability, making it ideal for preparing high-efficiency PV cell grid lines. However, with technological advancements and cost considerations, alternative compositions such as copper or aluminum paste can also be employed for the conductive paste 400, as these materials demonstrate adequate conductive performance under specific conditions. In the technical solution of the present disclosure, there is no particular requirement for the specific material of the conductive paste 400, provided it meets the requirements of diverse application scenarios. By simultaneously forming the conductive paste 400 on both upper and lower surfaces, the present disclosure enables the independent use of different materials on both the upper and lower surfaces (e.g., silver paste on the front surface and aluminum paste on the rear surface) without increasing the complexity of equipment components. One critical component of PV silver paste is the binder (e.g., phenolic or epoxy resins), which ensures stable bonding between silver particles and between the particles and the cell surface. A 20±2 μm thick PVA flexible film can be prepared on a carrier using a flatbed coating method. Additionally, the technically mature hot-embossing unit 310 guarantees precision in the PVA transfer coating after hot-embossing, while enabling rational design of the size and shape of the grid lines 500. For PVA removal, the water solubility of PVA can be modified through adjustments in alcoholysis degree, blending modification, or other methods, thereby achieving rapid dissolution of PVA at room temperature.

The selection of the transfer substrate 100 is critical to the success of the entire transfer process. In the present disclosure, the transfer substrate 100 is made of a flexible material, specifically flexible polyethylene terephthalate (PET)/polyimide (PI) plastic. The flexible material exhibits excellent elasticity and flexibility, allowing it to be bonded tightly to microscopic undulations and irregularities on the cell surface, thereby ensuring precise replication of the predefined grid line patterns during the transfer of the conductive paste 400. Furthermore, the flexible substrate can uniformly distribute pressure during compression, facilitating uniform dispersion of the conductive paste 400 across the substrate surface.

After the material of the conductive paste transfer layer 200 is fully dried and cured, a precision-engineered mold is employed to form the grid line pattern trenches 300 with specific shapes and dimensions onto the surface of the transfer layer using imprinting technology. The mold is typically fabricated from a high-hardness, high-precision material to ensure accuracy and consistency of the trenches during imprinting. During the imprinting process, the mold is brought into intimate contact with the conductive paste transfer layer 200. By applying appropriate pressure for an appropriate duration, the conductive paste 400 is guided by the mold to form the desired grid line pattern trenches 300. The present disclosure utilizes the mold-based imprinting method to form the grid line pattern trenches 300 in the conductive paste transfer layer 200. Compared to photolithography or etching processes, the mold-based imprinting approach significantly simplifies production by eliminating complex chemical treatments, relying solely on physical means to define the grid line patterns. The mold-based imprinting technique is highly efficient and rapid, enabling preparation of grid line patterns across numerous cells within short timeframes, thereby substantially boosting production efficiency.

Referring to FIGS. 2 and 3, FIG. 2 is a structural schematic diagram illustrating the distribution of cell grid lines according to an embodiment of the present disclosure. The final shape and distribution of the grid lines are adjustable based on design requirements. For example, the front grid line may include a busbar and a finger, while the rear grid line may include only a busbar. FIG. 3 is a cross-sectional schematic diagram illustrating the shape of the cell grid lines according to the embodiment of the present disclosure. The imprinting process of the present disclosure enables modification of the shape of the grid line 500 electrodes by altering the shape of the imprinting template. For instance, the template may be designed to produce grid lines with shapes such as isosceles triangles, rectangles, isosceles trapezoids, ovals, hexagons, or right-angled trapezoids.

In the manufacturing process of PV cells, the design and preparation of grid line patterns are critical, directly impacting the current collection efficiency of the cells. The grid line pattern includes a first grid line pattern with a trench depth of 10-50 μm and a trench width of 20-200 μm and a second grid line pattern with a trench depth of 6-25 μm and a trench width of 3-50 μm. By precisely controlling the design of the imprinting mold and process parameters (e.g., pressure, duration, and temperature), the method of the present disclosure enables the preparation of fine grid lines 500 with a trench depth of 6-25 μm and a trench width of 3-50 μm. The implementation of these fine grid lines 500 significantly reduces shading caused by the grid lines 500 while maintaining sufficient current collection capability of the cell, thereby enhancing the photoelectric conversion efficiency. Compared to the screen printing method, the present disclosure achieves dimensional control and manufacturability for the fine grid lines 500.

In the manufacturing process of the present disclosure, filling the conductive paste 400 into the grid line pattern trenches 300 is a critical step that directly affects the efficiency and stability of current transmission in the cell. This step can be subdivided into two precise sub-steps. First, a layer of conductive paste 400 is uniformly applied into the grid line pattern trenches 300 formed by imprinting. Subsequently, a doctor blade or similar tool is used to remove excess conductive paste 400 from edges and surfaces of the trenches with precise angle and pressure. In other words, the step of filling the conductive paste 400 into the grid line pattern trenches 300 includes: the conductive paste 400 is applied into the grid line pattern trenches 300 formed by imprinting, and the excess conductive paste 400 is scraped away. Uniform application of the conductive paste 400 within the grid line pattern trenches 300 ensures complete filling of each trench, thereby establishing reliable conductive pathways. The precise filling minimizes material waste during manufacturing and prevents failures such as grid line discontinuities.

During the heat transfer process, the selection of temperature, pressure, and duration is paramount. In the present disclosure, the transferring is performed at 80-180° C. and 1-20 MPa for 0.5-10 min. These parameter ranges ensure desired bonding between the transfer material (e.g., heat transfer film) and the transfer substrate 100 while avoiding material deformation caused by excessive heat. By precisely controlling the temperature, pressure, and duration, the accuracy and integrity of the transferred patterns are guaranteed. Furthermore, optimizing these parameters shortens production cycles and enhances efficiency without compromising transfer quality.

To further control the shape and dimensions of the grid lines 500, the process of transferring the conductive paste 400 from the grid line pattern trenches 300 onto the front and rear surfaces of the cell involves a two-stage treatment. The step of transferring the conductive paste 400 from the grid line pattern trenches 300 onto the cell surfaces includes: the transfer substrate 100 is first removed, and then the conductive paste transfer layer 200 is removed through a liquid dissolution method. Specifically, the transfer substrate 100 carrying the conductive paste 400 is removed first. Subsequently, the conductive paste transfer layer 200 overlying areas outside the grid line patterns is gently yet effectively removed through liquid dissolution. This two-stage process ensures the integrity and positional accuracy of the conductive paste 400 patterns, preventing potential displacement or damage during subsequent treatment steps.

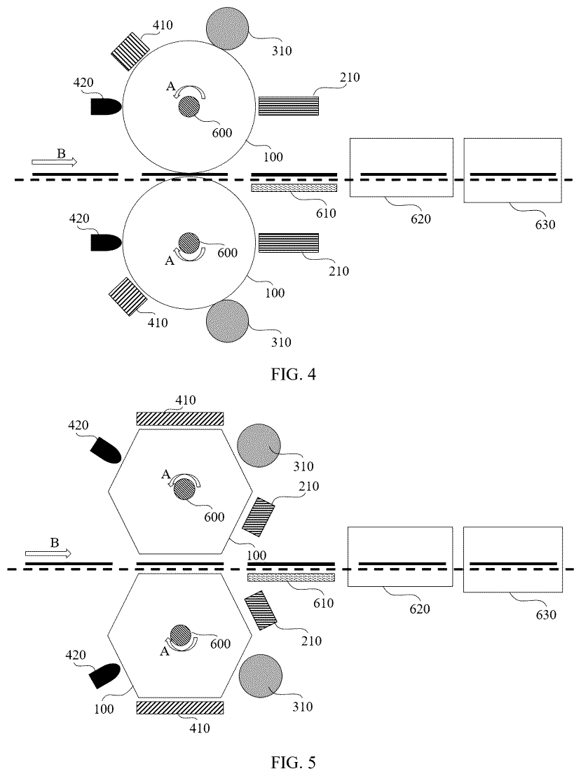

As shown in FIGS. 4 and 5, the present disclosure further provides a cell grid line preparation apparatus, which can implement the aforementioned cell grid line preparation method in a single integrated machine, thereby enhancing the integration and automation level of cell production lines. The components of the apparatus are described in detail below. The transfer substrate 100 serves as the initial carrier for transferring the conductive paste 400, featuring a high-precision and wear-resistant surface. The conductive paste transfer layer 200 is formed on the transfer substrate to ensure uniform coating and precise transfer of the paste.

Coating unit 210 is configured to coat the conductive paste transfer layer 200 onto the transfer substrate 100. Using high-precision coating techniques such as spraying, roller coating, or slot-die coating, this unit uniformly coats the conductive paste transfer layer 200 on the transfer substrate 100. The hot-embossing unit 310 is configured to form the grid line pattern trenches 300 in the conductive paste transfer layer 200. By applying precisely controlled temperature and pressure, this unit imprints fine grid line pattern trenches 300 into the conductive paste transfer layer 200, ensuring structural accuracy and consistency of the grid lines 500.

Paste filling unit 410 is configured to fill the grid line pattern trenches 300 with the conductive paste 400. After the grid line pattern trenches 300 are formed, this unit performs initial filling of the conductive paste 400. The primary material for the conductive paste 400 is silver paste. Silver is preferred due to its exceptional conductive performance and chemical stability, making it ideal for efficient PV cell grid lines. However, alternative conductive paste 400, such as copper or aluminum paste may also be used to align with technological advancements or cost optimization.

Scraping unit 420 is configured to remove excess conductive paste 400 using a precision doctor blade or similar tool. The process of removing excess conductive paste ensures complete filling of the conductive paste 400 into the trenches while eliminating residual paste outside the trenches, thereby guaranteeing dimensional accuracy and clean edges of the transferred grid lines 500.

Transfer unit 600 is configured to align and bond the conductive paste transfer layer 200 onto the cell surface, such that the conductive paste 400 in the grid line pattern trenches 300 is transferred to the cell surface. Precise alignment and appropriate pressure ensure that the conductive paste transfer layer is tightly bonded onto the cell surface. The transfer unit 600 primarily functions as a moving unit that moves the transfer substrate 100 via linear, vertical, or rotational motion to make the transfer layer 200 bonded onto the cell surface. Additionally, the transfer unit provides adjustable pressure and temperature. Any means of mechanism capable of bonding the conductive paste transfer layer 200 onto the cell surface qualifies as the transfer unit 600.

A transport mechanism is configured to deliver the cell to a station of the transfer unit 600. Featuring a highly stable and efficient transport path, the transport mechanism can accurately transport the cell (or a pre-processed cell) to the station of the transfer unit 600, ensuring seamless continuity and high efficiency of the production process. The primary transport method is compatible with existing PV cell production lines, such as a belt-based single-cell transport method.

The apparatus includes two systems, each including the transfer substrate 100, the coating unit 210, the hot-embossing unit 310, the paste filling unit 410, the scraping unit 420, and the transfer unit 600. The two systems are corresponding to the front and rear grid lines, respectively, enabling transfer of the conductive paste 400 on the front and rear surfaces of the cell simultaneously. The two identical, independent component systems operate in parallel to perform grid line transfer using identical processes on the front and rear surfaces of the cell. These systems maintain operational independence while achieving high synchronization, ensuring simultaneous yet interference-free transfer of the grid lines 500 on both the front and rear surfaces. The parallel processing design ensures simultaneous implementation of grid line transfer on the front and rear surfaces of the cell, dramatically reducing the production cycle time. The apparatus efficiently utilizes vertical space, maximizing facility floor space and equipment resource utilization. The present disclosure imposes no specific limitations on station quantity and combination. The specific implementation may include multiple station arrays adaptable to other automation equipment in the production line, eliminating the need to adjust the arrangement architecture of the automation equipment in the existing production line. The apparatus of the present disclosure integrates two fully independent yet synchronized processing systems, each including the transfer substrate 100, the coating unit 210, the hot-embossing unit 310, the paste filling unit 410, the scraping unit 420, and the transfer unit 600. The two systems are corresponding to the front and rear surfaces of the cell, respectively, enabling simultaneous conductive paste 400 transfer on the front and rear surfaces of the cell within a single machine.

Referring to FIG. 4, FIG. 4 is a structural schematic diagram of the cell grid line preparation apparatus according to an embodiment of the present disclosure. The transfer substrate 100 is configured as a cylindrical roller. The coating unit 210, the hot-embossing unit 310, the paste filling unit 410, and the scraping unit 420 are sequentially arranged on the cylindrical roller along its rotation direction. In this implementation, the cylindrical roller design of the transfer substrate 100 leverages the continuous rotation property of the cylindrical roller to arrange the critical processing components (the coating unit 210, the hot-embossing unit 310, the paste filling unit 410, and the scraping unit 420) sequentially and compactly along both the circumferential and rotation directions of the cylindrical roller. In the figure, A indicates the rotation direction, and B indicates a cell transport direction. The coating unit 210 first contacts the cylindrical roller-shaped transfer substrate 100 to uniformly coat a thin layer of conductive paste 400 on the substrate surface. Specifically, a slot-die coating method may be employed. Subsequently, the hot-embossing unit 310 precisely forms desired grid line pattern trenches 300 on the conductive paste 400 layer under preset temperature and pressure conditions. This process demands high precision and stability. The hot-embossing unit may also adopt a cylindrical roller design, such that two cylindrical roller surfaces imprint the pattern at identical surface speeds. By replacing the template in the hot-embossing unit 310, structural parameters such as electrode patterns and dimensions can be modified, ensuring compatibility with cells of varying designs. Next, the paste filling unit 410 fills additional conductive paste 400 into the fine trenches. The scraping unit 420 removes excess paste at predefined force and angle settings, refining the grid line patterns for clarity and completeness. Finally, the transfer unit 600 presses the conductive paste transfer layer 200 onto the cell surface, transferring the conductive paste 400 from the grid line pattern trenches 300 to the cell surface. In this implementation, the cylindrical roller-shaped transfer substrate 100 only needs rotation, rather than vertical movement. The continuous rotation design of the cylindrical roller-shaped transfer substrate 100 enables seamless integration of all processing steps. The compact arrangement of components along the circumferential direction of the cylindrical roller efficiently saves floor space, achieves more compact and rational production line layout, and facilitates daily maintenance and operation.

Referring to FIG. 5, FIG. 5 is a structural schematic diagram of the cell grid line preparation apparatus according to another embodiment of the present disclosure. In this embodiment, the transfer substrate 100 is provided with a polygonal cross-section including multiple flat surfaces. The coating unit 210, the hot-embossing unit 310, the paste filling unit 410, and the scraping unit 420 are sequentially arranged on corresponding surfaces of the transfer substrate 100. The sequence aligns with the rotation direction of the transfer substrate 100. In the figure, A indicates the rotation direction, and B indicates the cell transport direction. The transfer substrate 100 is designed with a polygonal cross-sectional structure to leverage its geometric properties. With the polygonal cross-section, the transfer substrate 100 includes multiple flat surfaces that provide stable working planes for each processing unit. In addition, the stations are adjusted continuously through rotation, ensuring process continuity and stability.

Specifically, the coating unit 210, the hot-embossing unit 310, the paste filling unit 410, and the scraping unit 420 are arranged on respective flat surfaces of the transfer substrate 100 in sequence, matching the rotation direction of the transfer substrate 100 to guarantee seamless processing step transition and operation. The coating unit 210 first acts on one flat surface of the transfer substrate 100, uniformly coating one conductive paste transfer layer 200. At the next station, the hot-embossing unit 310 precisely imprints grid line patterns on a second flat surface. By replacing the template in the hot-embossing unit 310, structural parameters such as electrode patterns and dimensions can be modified to accommodate different cell designs. The paste filling unit 410 fills the conductive paste 400 into the grid line pattern trenches in a third flat surface. The scraping unit 420 removes excess paste with fine scraping motions on a fourth surface. The transfer station corresponds to a fifth flat surface. This configuration allows five operations to occur simultaneously across five positions, achieving high continuity. The polygonal cross-section design of the transfer substrate 100 enables parallel processing of different processing steps on different flat surfaces, with each processing unit provided on one dedicated surface of the transfer substrate 100, ensuring process stability and uniformity. Besides, the polygon is preferably hexagon, as it provides an additional station for a supplementary step (e.g., cleaning) or maintenance.

In a further implementation solution, during the paste filling station, the surface of the transfer substrate 100 is in a horizontal state. In this state, a flatbed coating method is used to uniformly distribute the paste, facilitating excess paste recovery and enabling stable preparation of a 20±2 μm thick PVA-based flexible film on the carrier. In other words, the paste is uniformly distributed on the transfer substrate 100 in a horizontal state using a flatbed coating method. The horizontal state ensures uniform and consistent distribution of the paste on the transfer substrate 100, preventing flow or accumulation of the paste due to gravity or tilt, thereby guaranteeing uniformity and consistency of the conductive paste 400.

The polygon has flat surfaces, and the distance from each position to the center of the rotation axis is inconsistent. In this implementation, the apparatus further includes a moving unit. The moving unit synchronously adjusts heights of the upper and lower transfer substrates 100 of the cell. By adjusting the relative vertical positions of the center of the rotation axis, the upper and lower transfer substrates 100 apply pressure to the cell for transfer. For other peripheral components, corresponding moving units can also be provided as needed to accommodate the movement of the transfer substrates.

In conventional turntable-based screen printing methods, grid lines 500 can only be prepared on one surface. Moreover, due to size differences, separate screens are required for printing busbars and fingers, along with additional cell flipping structures. The present disclosure eliminates the turntable structure and integrates solely with a horizontal transport apparatus. By vertically arranging the components, simultaneous imprinting of both the upper and lower surfaces is achieved, enabling concurrent preparation of front and rear grid line electrodes, including all grid lines (busbars and fingers) on the front and rear surfaces of the cell. In this specific implementation, a transfer mechanism serves as an auxiliary unit to place the cell onto the lower transfer substrate 100. After imprinting, a suction cup relocates the cell to the transport unit (e.g., conveyor belt) for downstream transport to a subsequent station. For instance, buffer stations (upstream and downstream) can be integrated.

Specifically, the apparatus further includes a cleaning unit located before the coating station to clean a surface of the transfer substrate 100. At the cleaning station, a physical brushing method can be employed to remove residues from the surface of the transfer substrate 100. The addition of the cleaning station serves as a crucial supplement and optimization to the coating process, fundamentally improving the quality and efficiency of coating operations, thereby laying a solid foundation for manufacturing high-grade products.

Specifically, the apparatus further includes drying unit 610, cleaning unit 620, and sintering unit 630. The drying unit 610 is configured to dry the conductive paste 400. The cleaning unit 620 is configured to dissolve and remove the conductive paste transfer layer 200 through a solution method. The sintering unit 630 is configured to sinter the conductive paste 400. These supplementary units fully integrate the entire process flow.

Additionally, the present disclosure further provides a cell. The cell includes front and rear grid lines 500 prepared by the aforementioned cell grid line preparation method.

The technical solution of the present disclosure is described in detail below with reference to a specific embodiment. In this specific implementation, PVA is used to prepare the conductive paste transfer layer, and silver paste serves as the conductive paste. Insights into PV silver paste and investigations of novel hydrogen-bond mechanisms in PVA reveal that PVA exhibits no reactivity with the silver paste binder/solvent and only demonstrates weak adhesiveness, making it an ideal carrier for silver paste transfer. As shown in FIG. 1, a PVA layer is coated onto flexible PET/PI plastic and dried at 100-150° C. to form a 10-50 μm thick PVA film. Using an imprinting technique, a customized mold in a precision hot-embossing apparatus imprints 10-50 μm deep and 20-200 μm wide electrode pattern trenches for busbars, along with 6-25 μm high and 3-50 μm wide electrode pattern trenches for fingers in a direction perpendicular to the fingers. Meanwhile, another mold of the precision hot-embossing apparatus imprints 10-50 μm deep and 20-200 μm wide electrode pattern trenches for rear grid lines. Silver paste is simultaneously filled into the trenches of two PVA films formed by hot-embossing until the silver paste fully fills the trenches. Then excess paste is scraped off, and the two PVA films are flatly laminated onto the cell: one bonded to the front busbars/side busbars and the other to the rear busbars. Leveraging the adhesion properties between the PV silver paste and the cell, the transfer process is conducted by heating at 80-180° C. with 1-20 MPa pressure for 0.5-10 min. After the two PI films are removed, the silver paste and the PVA coating are tightly bonded to the cell. Subsequently, the PVA layer is dissolved in room-temperature water, such that the silver paste is transferred to the cell. Thus, through high-temperature sintering, the silver paste forms the front/rear electrode grid lines with specific patterns.

Based on the embossing and PVA transfer processes, the approach of simultaneous transfer on both the upper and lower parts of the cell is further adopted. It achieves the three steps of screen printing in a single operation, significantly improving production efficiency and reducing manufacturing costs. Additionally, the process of the transfer film is highly simplified, and it is simple to be transferred onto the cell, thereby facilitating industrial production.

The imprinting method offers the following advantages. The imprinting method enables nano-scale pattern preparation, providing higher resolution and accuracy than traditional methods, thereby enhancing the performance and efficiency of PV cells. The imprinting method demonstrates excellent reproducibility, allowing stable preparation of high-quality electrode patterns to ensure the stability and reliability of PV cells. Compared with other micro/nano preparation technologies, the imprinting method features lower costs and suitability for large-area preparation, effectively reducing production costs while improving production efficiency. The imprinting method can prepare various functional patterns, such as optical structures and surface-enhanced Raman scattering (SERS) structures, offering more possibilities for optimizing PV cell performance. Typically requiring no organic solvents, the imprinting method exhibits minimal environmental impact, aligns with green manufacturing requirements, and supports sustainable development. The advantages of nano-imprint technology further highlight the innovativeness and practicality of the technical solution in the present disclosure, demonstrating its superiority and potential in PV cell electrode preparation.

First, the preparation process for the high-resolution composite silver paste transfer film based on imprintable polymer material carriers (such as PVA carriers) can prepare micron-scale or even nano-scale electrode patterns. Compared with traditional screen printing technology, it offers higher resolution, thereby improving the performance and efficiency of PV cells. The preparation method employs PVA carriers as transfer media, featuring relatively simple procedures, convenient operation, and suitability for large-scale production. The PVA material is cost-effective, and this method can reduce material waste, thereby lowering production costs.

PVA exhibits no reactivity with the silver paste binder/solvent and demonstrates weak adhesiveness, making it an ideal carrier for silver paste transfer, facilitating tight adhesion between the silver paste and the cell. Compared with screen printing technology, this method achieves higher production efficiency, meeting the demands of large-scale production while improving production efficiency. The PVA carrier dissolves in room-temperature water, showing environmentally sustainable characteristics that help minimize environmental impact.

As described above, the present disclosure proposes a novel cell grid line preparation method. This method effectively reduces material consumption through precision transfer technology, thereby lowering production costs while achieving stable fabrication of small-sized cell grid lines. The method specifically includes the following steps. First, conductive paste transfer layers corresponding to the front and rear surfaces of the cell are respectively prepared on transfer substrates, where the transfer layers include grid line pattern trenches. The conductive paste is uniformly filled into the trenches while avoiding unnecessary paste accumulation through a controlled filling method. Subsequently, the front and rear conductive paste transfer layers are precisely aligned and bonded to the front and rear surfaces of the cell under appropriate pressure and temperature, transferring the conductive paste from the grid line pattern trenches onto the cell surface. Finally, the transferred conductive paste is converted into front and rear grid lines with excellent conductive performance and stability through thermal treatment or other methods.

The present disclosure particularly adopts a technical solution of simultaneous upper-lower transfer, enabling synchronous transfer of grid line patterns on the front and rear surfaces of the cell while balancing force distribution to prevent cell microcracks. This approach enhances the bonding level between the grid line and the cell surface, improving current collection efficiency. In the preparation of the conductive paste transfer layer in the present disclosure, PVA is used as the primary material due to its solubility, which facilitates successful silver paste transfer onto the cell. Meanwhile, the hot-embossing and transfer technology ensures robust bonding between the silver paste and the cell.

Additionally, the present disclosure further provides a cell grid line preparation apparatus. The apparatus implements the aforementioned cell grid line preparation method in a single integrated machine, enhancing automation and compactness of the cell production line. The apparatus includes transfer substrates, coating units, hot-embossing units, paste filling units, scraping units, transfer units, and transport mechanism, enabling simultaneous processing of the front and rear surfaces of the cell to significantly shorten production cycles. The transfer substrates employ a cylindrical roller-shaped or polygonal cross-sectional structure to ensure seamless integration of various processing steps and effectively reduce floor area. In summary, the cell grid line preparation method and apparatus of the present disclosure demonstrate outstanding advantages in material conservation, production efficiency, grid line quality, and stability, offering a novel solution for PV cell grid line preparation.

The above is merely a specific implementation of the present disclosure. Any improvements made based on the concept of the present disclosure shall be deemed to fall within the protection scope of the present disclosure.

What is claimed is:

1. A cell grid line preparation method, comprising following steps:
preparing conductive paste transfer layers corresponding to a front grid line and a rear grid line on transfer substrates, respectively, wherein the conductive paste transfer layers each comprise a grid line pattern trench;
filling conductive paste into the grid line pattern trench;
aligning and bonding the conductive paste transfer layer corresponding to the front grid line onto a front surface of a cell, and aligning and bonding the conductive paste transfer layer corresponding to the rear grid line onto a rear surface of the cell;
simultaneously applying pressure to the front surface and the rear surface of the cell, and transferring the conductive paste in the grid line pattern trenches onto the front surface and the rear surface of the cell; and
converting the transferred conductive paste into the front and rear grid lines.

2. The cell grid line preparation method according to claim 1, wherein the step of preparing the conductive paste transfer layers comprises: coating a water-soluble polymer material on the transfer substrate, drying, and controlling a thickness to fall within 10-50 μm.

3. The cell grid line preparation method according to claim 2, wherein the transfer substrate is a flexible material.

4. The cell grid line preparation method according to claim 2, wherein the grid line pattern trench is formed in the conductive paste transfer layer by imprinting with a mold.

5. The cell grid line preparation method according to claim 4, wherein a grid line pattern comprises a first grid line pattern with a trench depth of 10-50 μm and a trench width of 20-200 μm and a second grid line pattern with a trench depth 6-25 μm and a trench width 3-50 μm.

6. The cell grid line preparation method according to claim 4, wherein the step of filling the conductive paste into the grid line pattern trench comprises: filling the conductive paste into the imprinted grid line pattern trench, and scraping off excess conductive paste.

7. The cell grid line preparation method according to claim 1, wherein the step of transferring is performed at 80-180° C. and 1-20 MPa for 0.5-10 min.

8. The cell grid line preparation method according to claim 1, wherein the step of transferring the conductive paste in the grid line pattern trenches onto the front surface and the rear surface of the cell comprises: first removing the transfer substrate, and removing the conductive paste transfer layer through a liquid dissolution method.

9. A cell grid line preparation apparatus, comprising:
transfer substrates;
coating units, each configured to coat a conductive paste transfer layer onto the transfer substrate;
hot-embossing units, each configured to form a grid line pattern trench in the conductive paste transfer layer;
paste filling units, each configured to fill conductive paste into the grid line pattern trench;
scraping units, each configured to scrape off excess conductive paste;
transfer units, each configured to align and bond the conductive paste transfer layer onto a cell surface and transfer the conductive paste in the grid line pattern trench onto the cell surface; and
a transport mechanism, configured to transport a cell to a station of the transfer unit;
wherein the cell grid line preparation apparatus comprises the transfer substrates, the coating units, the hot-embossing units, the paste filling units, the scraping units, and the transfer units corresponding to a front grid line and a rear grid line, respectively, enabling simultaneous conductive paste transfer on a front surface and a rear surface of the cell.

10. The cell grid line preparation apparatus according to claim 9, wherein the transfer substrate is configured as a cylindrical roller; and the coating unit, the hot-embossing unit, the paste filling unit, and the scraping unit are sequentially arranged on the cylindrical roller along a rotation direction of the cylindrical roller.

11. The cell grid line preparation apparatus according to claim 9, wherein the transfer substrate is provided with a polygonal cross-section comprising a plurality of flat surfaces; and the coating unit, the hot-embossing unit, the paste filling unit, and the scraping unit are sequentially arranged on corresponding surfaces of the transfer substrate along a rotation direction of the transfer substrate.

12. The cell grid line preparation apparatus according to claim 11, further comprising a moving unit, wherein the moving unit is configured to synchronously adjust heights of upper and lower transfer substrates of the cell.

13. The cell grid line preparation apparatus according to claim 9, further comprising a cleaning unit located before a coating station to clean a surface of the transfer substrate.

14. The cell grid line preparation apparatus according to claim 9, further comprising a drying unit, a cleaning unit, and a sintering unit, wherein the drying unit is configured to dry the conductive paste; the cleaning unit is configured to dissolve and remove the conductive paste transfer layer through a solution method; and the sintering unit is configured to sinter the conductive paste.

15. A cell, comprising front and rear grid lines, wherein the front and rear grid lines of the cell are prepared by the cell grid line preparation method according to claim 1.

16. The cell according to claim 15, wherein in the cell grid line preparation method, the step of preparing the conductive paste transfer layers comprises: coating a water-soluble polymer material on the transfer substrate, drying, and controlling a thickness to fall within 10-50 μm.

17. The cell according to claim 16, wherein in the cell grid line preparation method, the transfer substrate is a flexible material.

18. The cell according to claim 16, wherein in the cell grid line preparation method, the grid line pattern trench is formed in the conductive paste transfer layer by imprinting with a mold.

19. The cell according to claim 18, wherein in the cell grid line preparation method, a grid line pattern comprises a first grid line pattern with a trench depth of 10-50 μm and a trench width of 20-200 μm and a second grid line pattern with a trench depth 6-25 μm and a trench width 3-50 μm.

20. The cell according to claim 18, wherein in the cell grid line preparation method, the step of filling the conductive paste into the grid line pattern trench comprises: filling the conductive paste into the imprinted grid line pattern trench, and scraping off excess conductive paste.
